(19) United States
(12) Patent Application Publication
(10) Pub. No.: US 2026/0271337 A1
(43) Pub. Date: Sep. 10, 2026

(54) SEMICONDUCTOR DEVICE AND METHOD OF MANUFACTURING THE SAME

(71) Applicants: Samsung Electronics Co., Ltd., Suwon-si (KR); IUCF-HYU (Industry-University Cooperation Foundation Hanyang University), Seoul (KR)

(72) Inventors: Kwanghee LEE, Suwon-si (KR); Jinseong PARK, Seoul (KR); Sangwook KIM, Suwon-si (KR); Seonghwan RYU, Seoul (KR); Jeeeun YANG, Suwon-si (KR)

(73) Assignees: Samsung Electronics Co., Ltd., Suwon-si (KR); IUCF-HYU (Industry-University Cooperation Foundation Hanyang University), Seoul (KR)

(21) Appl. No.: 19/371,917

(22) Filed: Oct. 28, 2025

(30) Foreign Application Priority Data
Mar. 6, 2025 (KR) 10-2025-0029209

(51) Int. Cl. H10D 30/67; H10B 12/00; H10D 30/01

(52) U.S. Cl. CPC H10D 30/6706; H10B 12/30; H10D 30/027; H10D 30/6755

(57) ABSTRACT

Provided are a semiconductor device and a method of manufacturing the semiconductor device. The semiconductor device includes an oxide semiconductor layer, a first electrode and a second electrode which are arranged apart from each other on the oxide semiconductor layer, a gate electrode arranged apart from the oxide semiconductor layer, a gate insulating layer arranged between the oxide semiconductor layer and the gate electrode, an insulating layer arranged on a surface of the oxide semiconductor layer, wherein the surface is not in contact with the first electrode, the second electrode, and the gate insulating layer, and a barrier layer arranged between the oxide semiconductor layer and the insulating layer.

### CROSS-REFERENCE TO RELATED APPLICATION

This application is based on and claims priority under 35 U.S.C. § 119 to Korean Patent Application No. 10-2025-0029209, filed on Mar. 6, 2025, in the Korean Intellectual Property Office, the disclosure of which is incorporated by reference herein in its entirety.

### BACKGROUND

### 1. Field

The disclosure relates to a semiconductor device and a method of manufacturing the semiconductor device.

### 2. Description of the Related Art

A transistor is a semiconductor device may be configured to perform the function of electrical switching and may be used in various integrated circuit (IC) devices, including memory, driver integrated circuits (ICs), logic devices, and/or the like. To increase the degree of integration of IC devices, the space occupied by transistors included in IC devices has been reduced; thereby, research is being conducted to reduce the size of transistors while maintaining and/or improving the performance of the transistors.

Oxide semiconductor devices may be included in transparent semiconductor devices and may include an oxide semiconductor characterized by a wide band gap of 3.0 eV or greater. In at least some examples, the oxide semiconductor may include a transparent oxide. Oxide semiconductor devices used in large-area display driving devices may have characteristics of low off-current, high on/off ratio, etc. The degree of integration may be increased by applying an oxide semiconductor device having the aforementioned characteristics to a memory or logic device or stacking the oxide semiconductor device on a Si-based device.

However, the short-channel effect due to scaling-down of oxide semiconductor devices may degrade the performance of oxide semiconductor devices. Therefore, research is being conducted to protect against this degradation.

### SUMMARY

Provided are a semiconductor device capable of reducing deterioration of an oxide semiconductor layer, a method of manufacturing the semiconductor device, and an electronic apparatus including the semiconductor device.

Additional aspects will be set forth in part in the description which follows and, in part, will be apparent from the description, or may be learned by practice of the presented embodiments of the disclosure.

According to an aspect of the disclosure, a semiconductor device includes an oxide semiconductor layer; a first electrode and a second electrode spaced apart from each other on the oxide semiconductor layer; a gate electrode spaced apart from the oxide semiconductor layer, a gate insulating layer between the oxide semiconductor layer and the gate electrode; an insulating layer facing a surface of the oxide semiconductor layer, the surface of the oxide semiconductor layer not in contact with the first electrode, the second electrode, and the gate insulating layer; and a barrier layer between the oxide semiconductor layer and the insulating layer, and including a third element, an oxide formation energy of the third element is less than an oxide formation energy of a first element included in the oxide semiconductor layer and less than an oxide formation energy of a second element included in the insulating layer.

The oxide semiconductor layer may include at least one of indium (In), gallium (Ga), tin (Sn), cadmium (Cd), germanium (Ge), hafnium (Hf), or zinc (Zn).

The third element may have oxide formation energy of −800 kilojoules per mole (kJ/mol) or less at 1 atmosphere and at 100 degrees Celsius (° C.).

The barrier layer may include at least one of lithium (Li), beryllium (Be), magnesium (Mg), aluminum (Al), calcium (Ca), scandium (Sc), strontium (Sr), yttrium (Y), zirconium (Zr), barium (Ba), lanthanum (La), or hafnium (Hf).

A thickness of the barrier layer may be less than or equal to a thickness of the oxide semiconductor layer.

The barrier layer may be in contact with the surface of the oxide semiconductor layer not in contact with the first electrode, the second electrode, and the gate insulating layer.

The barrier layer may be in contact with an entire surface of the oxide semiconductor layer, wherein the entirety of the surface not in contact with the first electrode, the second electrode, and the gate insulating layer.

The insulating layer may include at least one of a silicon oxide or a silicon nitride.

The gate insulating layer may include at least one of hafnium (Hf), zirconium (Zr), aluminum (Al), or silicon (Si).

The third element may also be included in the oxide semiconductor layer, and a content of the third element in the barrier layer may be greater than a content of the third element in the oxide semiconductor layer.

The first electrode, the oxide semiconductor layer, and the second electrode may be sequentially arranged in a first direction perpendicular to a surface of the first electrode, and the barrier layer, the oxide semiconductor layer, the gate insulating layer, and the gate electrode may be sequentially arranged in a second direction perpendicular to the first direction.

The oxide semiconductor layer may include, in a cross-sectional view perpendicular to the surface of the first electrode, a first area extending in the second direction, and a second area extending from the first electrode towards the second electrode.

The semiconductor device may further include a capacitor electrically connected to the oxide semiconductor layer, wherein the first electrode may be a component of a bit line, and the gate electrode may be a component of a word line.

According to another aspect of the disclosure, a method of manufacturing a semiconductor device includes forming a first insulating layer on a first electrode such that the first insulating layer defines an opening exposing the first electrode, the first insulating layer including a first element, forming a barrier layer on the first insulating layer, the barrier layer including a second element having less oxide formation energy than the first element included in the first insulating layer, forming an oxide semiconductor layer on the first electrode and the barrier layer, sequentially forming a gate insulating layer and a gate electrode on a first surface of the oxide semiconductor layer, and forming a second electrode on a second surface of the oxide semiconductor layer, the second surface being different from the first surface of the oxide semiconductor layer.

The forming of the gate insulating layer and the gate electrode may include etching the gate insulating layer and the gate electrode such that a surface of the oxide semiconductor layer is exposed, wherein the surface of the oxide semiconductor layer which is exposed is parallel to a surface of the first electrode, etching the gate insulating layer and the gate electrode such that the gate insulating layer is divided into a first gate insulating layer and a second gate insulating layer, the gate electrode is divided into a first gate electrode and a second gate electrode, and an upper surface of the first insulating layer is exposed, and partially etching the first gate electrode and the second gate electrode such that a distance of upper surfaces of the first gate electrode and the second electrode from the first electrode is less than a distance of upper surfaces of the first gate insulating layer and the second gate insulating layer from the first electrode.

The second element included in the barrier layer may have less oxide formation energy than a third element included in the oxide semiconductor layer.

The second element may have oxide formation energy of −800 kilojoules per mole (kJ/mol) or less at 1 atmosphere and at 100° C.

The barrier layer may be an oxide including at least one of lithium (Li), beryllium (Be), magnesium (Mg), aluminum (Al), calcium (Ca), scandium (Sc), strontium (Sr), yttrium (Y), zirconium (Zr), barium (Ba), lanthanum (La), or hafnium (Hf).

A thickness of the barrier layer may be less than or equal to a thickness of the oxide semiconductor layer.

The second element may also be included in the oxide semiconductor layer, and a content of the second element in the barrier layer may be greater than a content of the second element in the oxide semiconductor layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram of a semiconductor device according to at least one example embodiment;

FIG. 2 is a transmission electron microscopy (TEM) image of a semiconductor device before hydrogen exposure in a comparative example;

FIG. 3. is a TEM image of a semiconductor device after hydrogen exposure in a comparative example;

FIG. 4 is a TEM image of a semiconductor device after hydrogen exposure, according to at least one example embodiment;

FIG. 5 shows EDS analysis results of a semiconductor device in which an aluminum oxide is applied as a barrier layer, according to at least one example embodiment;

FIG. 6 shows results of EDS analysis of a semiconductor device in which a hafnium oxide is applied as a barrier layer, according to at least one example embodiment;

FIG. 7 is a diagram of a semiconductor device including a barrier layer, according to at least one example embodiment;

FIG. 8 is a diagram of a semiconductor device according to at least one example embodiment;

FIG. 9 is a flowchart illustrating a method of manufacturing a semiconductor device according to at least one example embodiment;

FIGS. 10 to 17 are each a reference diagram illustrating a method of manufacturing the semiconductor device of FIG. 8;

FIG. 18 is a perspective view illustrating a schematic structure of a vertically stacked memory apparatus according to at least one example embodiment;

FIG. 19 is a perspective view illustrating a schematic structure of a vertically stacked memory apparatus according to at least one example embodiment;

FIG. 20 is a block diagram illustrating an electronic system according to at least one example embodiment; and

FIG. 21 is a block diagram of an electronic system according to at least one example embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, an oxide semiconductor thin film according to various embodiments and a semiconductor device including the same are described in detail with reference to the attached drawings. In the drawings, like reference numerals in the drawings denote like elements, and sizes of components in the drawings may be exaggerated for clarity and convenience of explanation.

An expression used in the singular encompasses the expression of the plural unless it has a clearly different meaning in the context. When a portion “includes” a component, another component may be further included, rather than excluding the existence of the other component, unless otherwise described. Sizes or thicknesses of components in the drawings may be arbitrarily exaggerated for convenience of explanation. Further, when a certain material layer is described as being arranged on a substrate or another layer, the material layer may be in contact with the other layer, or there may be a third layer between the material layer and the other layer. In embodiments, materials constituting each layer are provided merely as an example, and other materials may also be used.

Moreover, terms like “part,” “module,” etc., which refer to a unit processing at least one function or operation, may be implemented by processing circuitry, such as a hardware, a software, or a combination thereof. For example, unless expressly indicated otherwise, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components.

The particular implementations shown and described herein are illustrative examples of embodiments and are not intended to otherwise limit the scope of embodiments in any way. For the sake of brevity, conventional electronics, control systems, software development and other functional aspects of the systems may not be described in detail.

Furthermore, the connecting lines, or connectors shown in the various figures presented are intended to represent exemplary functional relations and/or physical or logical couplings between the various elements. It should be noted that many alternative or additional functional relations, physical connections or logical connections may be present in a practical device.

It will also be understood that spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly; and the term “upper portion” or “on” may also include “to be present above, below, in the left and right sides on a non-contact basis” as well as “to be on the top, bottom, left, and right portions in directly contact with”.

The use of the terms “a” and “an” and “the” and similar referents in the context of describing embodiments (especially in the context of the following claims) are to be construed to cover both the singular and the plural.

The expression such as “at least” used to list elements is intended to limit a list of entire elements, rather than individual elements in the list. For example, expressions such as “at least one of A, B, and C” or “at least one selected from the group consisting of A, B, and C” may be interpreted as only A, only B, only C, or a combination of two or more of A, B, and C, e.g., ABC, AB, BC, and AC.

When the terms such as “about” or “substantially” are used in relation to numerical values, the relevant numerical value may be construed as including a manufacturing or operation deviation (e.g., ±10 %) of the stated numerical value. In addition, when the expressions such as “generally” and “substantially” are used in relation to a geometric shape, the geometric precision may not be required, and the intention is that the degree of tolerance regarding the shape is within the scope of embodiments of the disclosure. Moreover, regardless of whether a numerical value of a shape is limited by using “about” or “substantially”, such numerical value or shape should be understood as including a manufacturing or operation deviation (e.g., ±10 %) of the stated numerical value.

While such terms as “first,” “second,” etc., may be used to describe various components, such components must not be limited to the above terms. The above terms are used only to distinguish one component from another.

The use of any and all examples, or exemplary language provided herein, is intended merely to better illuminate technical ideas and does not pose a limitation on the scope of embodiments unless otherwise claimed.

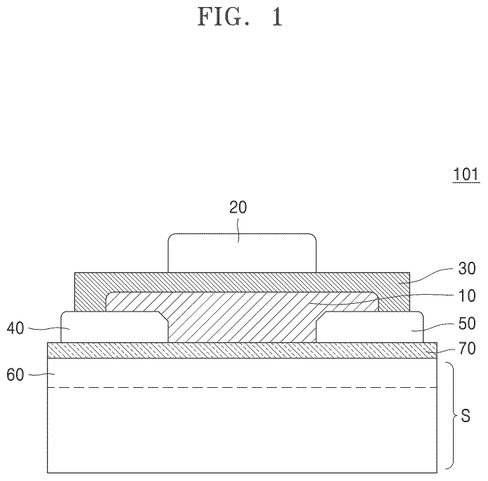

FIG. 1 is a diagram of a semiconductor device 101 according to at least one example embodiment. The semiconductor device 101 of FIG. 1 may include a substrate S, an oxide semiconductor layer 10 arranged on the substrate S, a gate electrode 20 arranged apart from the oxide semiconductor layer 10, a gate insulating layer 30 arranged between the oxide semiconductor layer 10 and the gate electrode 20, a first electrode 40 and a second electrode 50 arranged on the oxide semiconductor layer 10 and apart from each other, and an insulator layer 60 at an upper surface of the substrate S.

The substrate S may be an insulating substrate or a semiconductor substrate on which an insulating layer 60 is formed. However, the example embodiments are not limited thereto. For example, the substrate S may be a semiconductor substrate. In at least some example embodiments, the substrate S may include, for example, Si, Ge, SiGe, Group III-V semiconductor materials, and/or the like. The substrate S may be, for example, a silicon substrate on which a silicon oxide is formed; however, the disclosure is not limited thereto. The substrate S may be a silicon substrate on which a silicon nitride is formed.

The oxide semiconductor layer 10 may be arranged on the substrate S. The oxide semiconductor layer 10 according to at least one example embodiment may include an oxide including at least one metal. The oxide semiconductor layer 10 according to at least one example embodiment may include one or more Groups 12, 13, and 14 metals, such as indium (In), gallium (Ga), tin (Sn), cadmium (Cd), aluminum (Al), germanium (Ge), hafnium (Hf), or zinc (Zn) and an oxide of a material selected from combinations thereof. For example, the oxide semiconductor layer 10 may have a single-layer structure or a multi-layer structure. The thickness of the oxide semiconductor layer 10 may be about 10 nanometers (nm) or less, about 8 nm or less, or about 7 nm or less. The thickness of a layer may refer to an average thickness. When the semiconductor device 101 is a component of a memory cell or a transistor, the oxide semiconductor layer 10 may be a channel layer.

The gate electrode 20 may be arranged apart from the oxide semiconductor layer 10. The gate electrode 20 may include a conductive material (e.g., a zero-bang gap material and/or a material with a Fermi level included in a conduction band). For example, the gate electrode 20 may include at least one of a metal, a metal nitride, and a transparent conductive oxide (TCO). When the semiconductor device 101 is a component of a memory cell, the gate electrode 20 may be a partial area of a word line.

The gate insulating layer 30 may be arranged between the oxide semiconductor layer 10 and the gate electrode 20. The gate insulating layer 30 and the insulator layer 60 may each include an insulator material. For example, the gate insulating layer 30 and the insulator layer 60 may include each an oxide including at least one of hafnium (Hf), zirconium (Zr), aluminum (Al), silicon (Si), and/or the like.

The first electrode 40 and the second electrode 50 may be spaced apart from each other on the oxide semiconductor layer 10. For example, in at least one example, the semiconductor device 101 may be a top-gate structure, wherein the first electrode 40, the second electrode 50, and the gate electrode 20 are arranged on the same surface of the oxide semiconductor layer 10. However, the disclosure is not limited thereto. For example, the semiconductor device 101 may be bottom-gate structure, wherein first electrode 40 and the second electrode 50 are arranged on a lower surface of the oxide semiconductor layer 10, and the gate electrode 20 are arranged on an upper surface of the oxide semiconductor layer 10. The first electrode 40 may be a source electrode, and the second electrode 50 may be a drain electrode.

A barrier layer 70 may be arranged between the oxide semiconductor layer 10 and the insulating layer 60. The barrier layer 70 may be in contact with a surface of the oxide semiconductor layer 10, wherein the surface of the oxide semiconductor layer 10 is not in contact with (e.g., is not facing and/or is on a side opposite to) the first electrode 40, the second electrode 50, and/or the gate insulating layer 30. For example, in at least one example, wherein the semiconductor device 101 is a top-gate structure, the barrier layer 70 may be in contact with an entirety of the surface of the oxide semiconductor layer 10, wherein the surface is not in contact with the first electrode 40, the second electrode 50, and the gate insulating layer 30. The thickness of the barrier layer 70 may be less than or equal to the thickness of the oxide semiconductor layer 10. For example, the thickness of the barrier layer 70 may be less than or equal to the thickness of the oxide semiconductor layer 10.

The barrier layer 70 may include a material having less oxide formation energy than a material included in the oxide semiconductor layer 10 and a material included in the insulating layer 60. For example, the barrier layer 70 may include a third element having less oxide formation energy than a first element included in the oxide semiconductor layer 10 and a second element included in the insulating layer 60. The first element, the second element, and the third element may be different from each other. The third element may also be included in the oxide semiconductor layer 10 and the insulating layer 60; however, a content of the third element in the barrier layer 70 may be highest. The third element may have oxide formation energy of −800 kilojoules per mole (kJ/mol) or less at about 1 atmosphere and at about 100° C.

The barrier layer 70 may include a metal oxide including at least one metal. The barrier layer 70 may be an oxide including at least one of lithium (Li), beryllium (Be), magnesium (Mg), aluminum (Al), calcium (Ca), scandium (Sc), strontium (Sr), yttrium (Y), zirconium (Zr), barium (Ba), lanthanum (La), and/or hafnium (Hf).

For example, in at least one example embodiment, when the oxide semiconductor layer 10 is an oxide including at least one of indium (In), gallium (Ga), and/or tin (Sn), and the insulating layer 60 is an oxide including silicon (Si), the barrier layer 70 may be an oxide including aluminum (Al).

A hydrogen exposure may occur in post-processing of the semiconductor device 101. The barrier layer 70 according to at least one example embodiment may protect against (e.g., prevent and/or mitigate against) diffusion between the materials of the oxide semiconductor layer 10 and the insulating layer 60 to reduce deterioration of the oxide semiconductor layer 10.

As a surface of the oxide semiconductor layer 10 is in contact with the first electrode 40, the second electrode 50, and the gate insulating layer 30, even when the hydrogen exposure occurs, the first electrode 40, the second electrode 50, and the gate insulating layer 30 may protect against the deterioration of the oxide semiconductor layer 10 and therefore may function similarly to the barrier layer 70. However, when the insulating layer 60 includes, for example, silicon (Si) of Group 14, hydrogen may serve as a catalyst, and the oxide semiconductor layer 10 may be deteriorated by the interchange between the material included in the insulating layer 60 and the material included in the oxide semiconductor layer 10.

As the semiconductor device according to at least one example embodiment includes the barrier layer 70 including a material having low oxide formation energy between the oxide semiconductor layer 10 and the insulating layer 60, even when hydrogen is supplied, oxygen dissociation of a material included in the barrier layer 70 may be reduced. Accordingly, interchange between the material included in the oxide semiconductor layer 10 and the material included in the insulating layer 60 may not occur, which leads to reduced deterioration of the oxide semiconductor layer 10.

To confirm the performance of the barrier layer, as a comparative example, an oxide semiconductor layer including indium, tin, and gallium was formed on an insulating layer including a silicon oxide, and a gate insulating layer including an aluminum oxide, a source electrode, a drain electrode, and a gate electrode were formed on the oxide semiconductor layer. The semiconductor device of the comparative example was exposed to a hydrogen atmosphere at about 600° C. for about 1 hour.

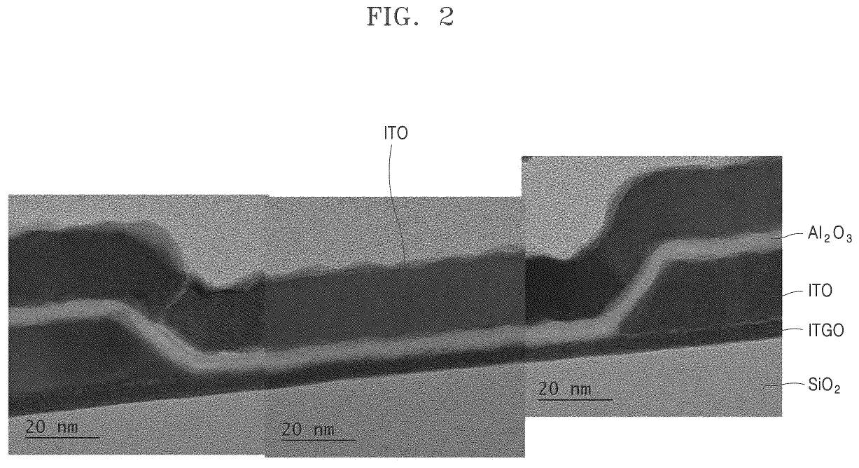

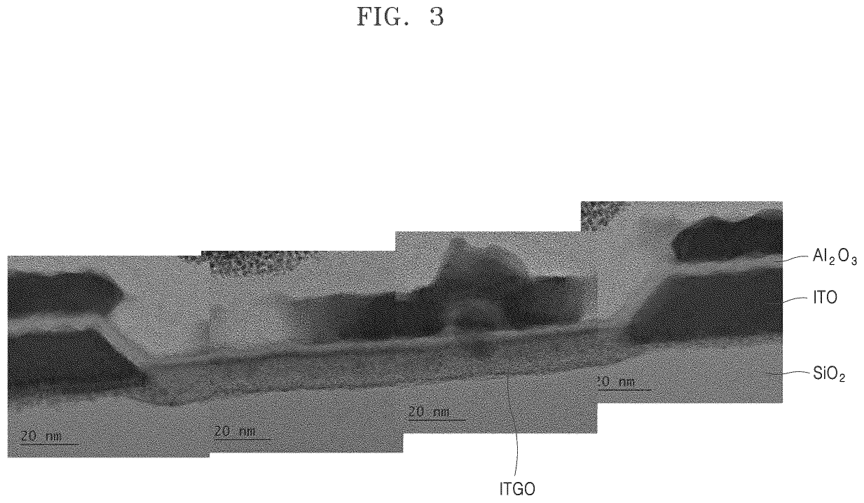

FIG. 2 is a transmission electron microscopy (TEM) image of the semiconductor device before hydrogen exposure in the comparative example, and FIG. 3 is a TEM image of the semiconductor device after hydrogen exposure in the comparative example. When comparing FIGS. 2 and 3, due to the hydrogen exposure, the oxide semiconductor layer of the semiconductor device was deteriorated in the comparative example. Deterioration of the source electrode and the drain electrode was relatively insignificant. This suggests that the gate insulating layer functioned as a barrier layer of the source electrode and the drain electrode against hydrogen. It is assumed that the metals of the gate insulating layer (30), the oxide semiconductor layer (10), and the insulating layer (70) were exchanged due to hydrogen serving as a catalyst.

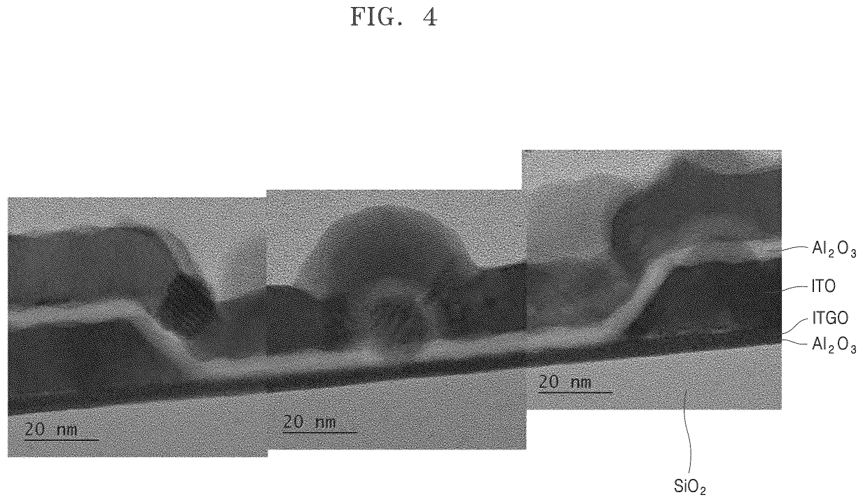

FIG. 4 is a TEM image of a semiconductor device after hydrogen exposure according to at least one example embodiment. The semiconductor device illustrated in FIG. 4 includes a barrier layer between the insulating layer and the oxide semiconductor layer, as compared to the semiconductor device of the comparative example. The barrier layer included in FIG. 4 includes an aluminum oxide. The semiconductor device of the example embodiment was exposed to a hydrogen atmosphere at about 600° C. for about 1 hour.

Referring to FIG. 4, in the semiconductor device according to at least one example embodiment, the oxide semiconductor layer may not be deteriorated even after hydrogen exposure. This is because the barrier layer blocks material exchange between the oxide semiconductor layer and the insulating layer.

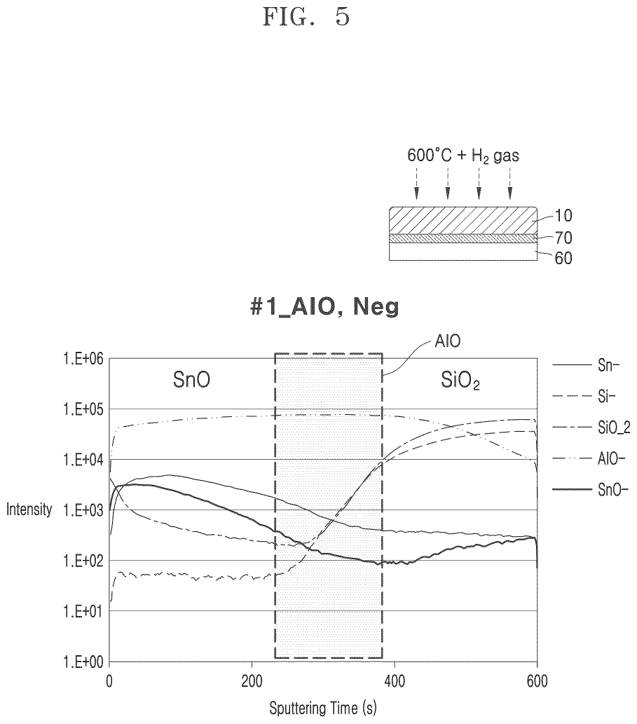

FIG. 5 shows Secondary Ion Mass Spectrometry (SIMS) analysis results of a semiconductor device in which an aluminum oxide is applied as a barrier layer, according to at least one example embodiment. A tin oxide was used as the oxide semiconductor layer, an aluminum oxide was used as the barrier layer, and a silicon oxide was used as the insulating layer. After the semiconductor device was exposed to a hydrogen atmosphere at 600° C. (for example, an atmosphere including 96 % N₂ and 4 % H₂) for 1 hour, the components were analyzed. It was confirmed that the aluminum oxide was diffused to the oxide semiconductor layer. However, diffusion of tin and tin oxide to the insulating layer was insignificant. In addition, diffusion of silicon and silicon oxide to the oxide semiconductor layer 10 was also insignificant. It is assumed that the aluminum oxide suppressed the material exchange between the tin oxide and the silicon oxide.

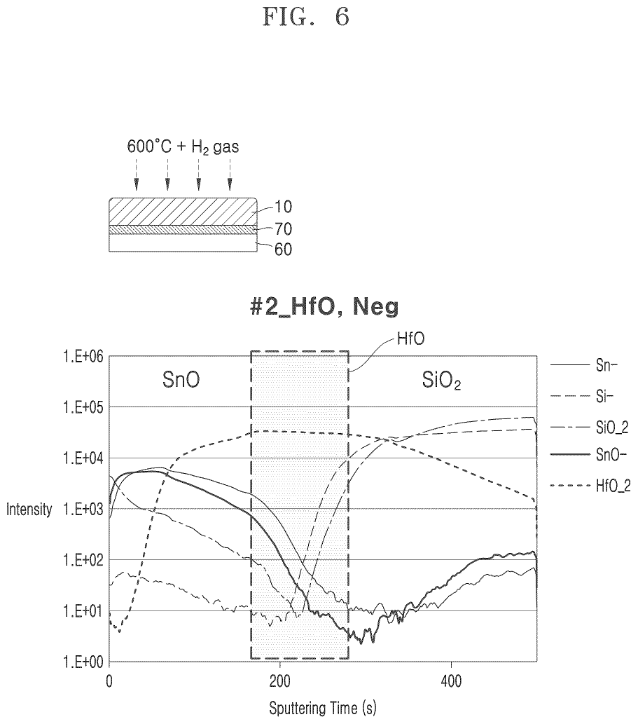

FIG. 6 shows SIMS analysis results of a semiconductor device in which a hafnium oxide is applied as a barrier layer, according to at least one example embodiment. A tin oxide was used as the semiconductor layer, a hafnium oxide was used as the barrier layer, and a silicon oxide was used as the insulating layer. After the semiconductor device was exposed to a hydrogen atmosphere at 600° C. for 1 hour, the components were analyzed. It was confirmed that the hafnium oxide was diffused to the oxide semiconductor layer. However, diffusion of tin and tin oxide to the insulating layer was insignificant. In addition, diffusion of silicon and silicon oxide to the oxide semiconductor layer was also insignificant. It is assumed that the hafnium oxide suppressed the material exchange between the tin oxide and the silicon oxide.

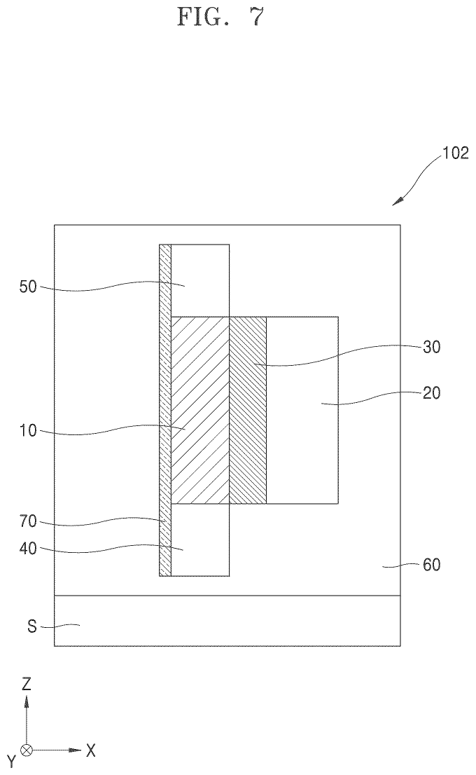

FIG. 7 is a diagram of a semiconductor device 102 including a barrier layer according to at least one example embodiment. Referring to FIG. 7, the semiconductor device 102 may include the substrate S, the first electrode 40 arranged on the substrate S, the oxide semiconductor layer 10 arranged on the first electrode 40, and the second electrode 50 arranged on the oxide semiconductor layer 10.

The substrate S may be an insulating substrate, a semiconductor substrate on which an insulating layer is formed, and/or, a semiconductor substrate.

The first electrode 40 may include a conductive material, such as a metal material. The first electrode 40 may include at least one of tungsten (W), cobalt (Co), nickel (Ni), iron (Fe), titanium (Ti), molybdenum (Mo), chrome (Cr), zirconium (Zr), hafnium (Hf), niobium (Nb), tantalum (Ta), silver (Ag), gold (Au), aluminum (Al), copper (Cu), tin (Sn), vanadium (V), ruthenium (Ru), platinum (Pt), zinc (An), magnesium (Mg), and/or the like. The first electrode 40 may be arranged apart from the substrate S.

The oxide semiconductor layer 10 may be an oxide including at least one of indium (In), gallium (Ga), zinc (Zn), aluminum (Al), tin (Sn), hafnium (Hf), and/or the like. As the oxide semiconductor layer 10 is described above in relation to FIG. 1, specific description thereof is omitted. The oxide semiconductor layer 10 may be arranged in such a manner that a longitudinal direction thereof is a direction perpendicular to the substrate S (Z-axis direction). In the disclosure, the longitudinal direction may refer to a direction of a greater length of a component illustrated in the drawings.

The second electrode 50 may be arranged on the oxide semiconductor layer 10. The first electrode 40 and the second electrode 50 may be arranged apart from each other in the direction perpendicular to the substrate S (Z-axis direction). For example, the first electrode 40, the oxide semiconductor layer 10, and the second electrode 50 may be arranged in line in the direction perpendicular to the substrate S or the thickness direction of the first electrode 40 (Z-axis direction). The second electrode 50 may include a conductive material, such as a metal material. The second electrode 50 may include the same or a different conductive material as included in the first electrode 40.

The gate electrode 20 may be arranged on one side of the oxide semiconductor layer 10. The gate insulating layer 30 may be arranged between the oxide semiconductor layer 10 and the gate electrode 20. The gate electrode 20 may include a conductive material, such as at least one of a metal, a metal nitride, and a TCO. The gate insulating layer 30 may include an insulator material, such as an oxide including at least one of hafnium (Hf), zirconium (Zr), aluminum (Al), and silicon (Si).

The gate electrode 20 may be arranged in such a manner that the longitudinal direction thereof (Z-axis direction) is the direction perpendicular to the substrate S. The oxide semiconductor layer 10, the gate insulating layer 30, and the gate electrode 20 may be arranged in line in a direction horizontal to the substrate S (X-axis direction).

The barrier layer 70 may be arranged on a surface of the oxide semiconductor layer 10, wherein the surface of the oxide semiconductor layer 10 is not in contact with the first electrode 40, the second electrode 50, and the gate insulating layer 30. Then, the insulating layer 60 filling up an empty space of the semiconductor device may be arranged. That is, the barrier layer 70 may be arranged between the oxide semiconductor layer 10 and the insulating layer 60. The barrier layer 70 may include a third element having less oxide formation energy than a first element included in the oxide semiconductor layer 10 and a second element included in the insulating layer 60. For example, the third element may have oxide formation energy of −800 kJ/mol or less at about 1 atmosphere (atm) and at about 100° C. The barrier layer 70 may be an oxide including at least one of lithium (Li), beryllium (Be), magnesium (Mg), aluminum (Al), calcium (Ca), scandium (Sc), strontium (Sr), yttrium (Y), zirconium (Zr), barium (Ba), lanthanum (La), and/or hafnium (Hf).

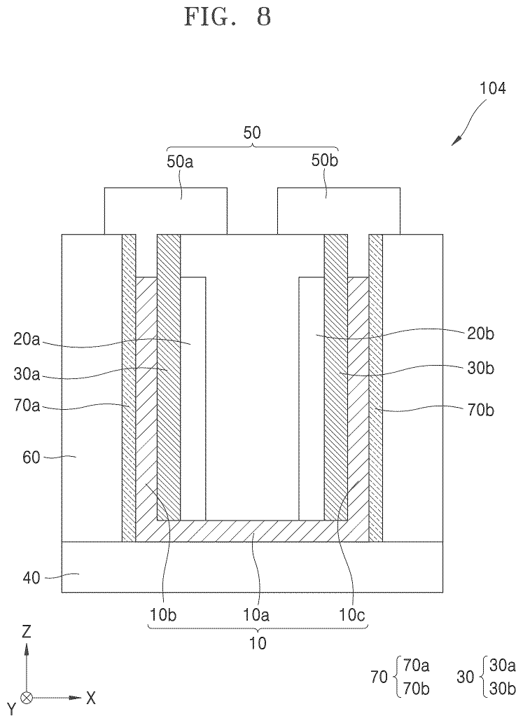

FIG. 8 is a diagram of a semiconductor device 104 according to at least one example embodiment. In FIG. 8, components denoted by the same reference numerals as in the aforementioned drawings have substantially the same configuration and effects as described above, and thus any redundant description will be omitted.

The semiconductor device 104 illustrated in FIG. 8 may include the first electrode 40 and the oxide semiconductor layer 10 arranged on the first electrode 40.

In a cross-section view perpendicular to the surface of the first electrode 40, the oxide semiconductor layer 10 may include a first area extending in a direction parallel with the surface of the first electrode 40 and a second area extending in a direction from the first electrode 40 towards the second electrode 50. For example, the oxide semiconductor layer 10 may have a U-shaped cross-section. The oxide semiconductor layer 10 may include a bottom portion 10a in parallel with the surface of the first electrode 40, a first vertical extension 10b extending from one end of the bottom portion 10a in a direction perpendicular to the surface of the first electrode 40 (Z-axis direction), and a second vertical extension 10c extending from the other end of the bottom portion 10a in the direction perpendicular to the surface of the substrate S (Z-axis direction). A lower surface of the bottom portion 10a may be referred to as a lower surface of the oxide semiconductor layer 10, and external surfaces of the first vertical extension 10b and the second vertical extension 10c may be referred to as outside surfaces of the oxide semiconductor layer 10. The width of the bottom portion 10a of the oxide semiconductor layer 10 may be defined as the width of the oxide semiconductor layer 10.

The second electrode 50 may be arranged on the oxide semiconductor layer 10. The second electrode 50 may function as a landing pad. The second electrode 50 may include a first sub-electrode 50a and a second sub-electrode 50b. The first sub-electrode 50a may be electrically connected to the first vertical extension 10b. The second sub-electrode 50b may be electrically connected to the second vertical extension 10c. The first sub-electrode 50a may not be electrically connected to the second sub-electrode 50b.

In at least one example embodiment, an upper portion of each of the first sub-electrode 50a and the second sub-electrode 50b may have a first width in a first horizontal direction (X-axis direction), and a lower portion of each of the first sub-electrode 50a and the second sub-electrode 50b may have a second width in the first horizontal direction (X-axis direction), which is less than the first width. Each of the first sub-electrode 50a and the second sub-electrode 50b may have a t-shaped vertical cross-section.

A bottom surface of the lower portion of the first sub-electrode 50a may be arranged on an upper surface of the first vertical extension 10b, and a bottom surface of the lower portion of the second sub-electrode 50b may be arranged on an upper surface of the second vertical extension 10c. A bottom surface of the lower portion of the second electrode 50 may be arranged at a higher level than an upper surface of a first gate electrode 20a and/or a second gate electrode 20b, and a part of a side wall of the lower portion of the second electrode 50 may be covered by a first gate insulating layer 30a and/or a second gate insulating layer 30b.

The gate electrode 20 may include the first gate electrode 20a arranged apart from the first vertical extension 10b and the second gate electrode 20b arranged apart from the second vertical extension 10c. In addition, the gate insulating layer 30 may include the first gate insulating layer 30a arranged between the first vertical extension 10b and the first gate electrode 20a and the second gate insulating layer 30b arranged between the second vertical extension 10c and the second gate electrode 20b.

The first gate electrode 20a and/or the second gate electrode 20b may extend in a second horizontal direction (Y-axis direction). The first gate electrode 20a and the second gate electrode 20b may be arranged apart from each other.

The semiconductor device 104 may have a vertical channel transistor (VCT) structure including a vertical channel region extending in a direction perpendicular to the first electrode 40 (X-axis direction).

When the same electrical signal is applied to the first gate electrode 20a and the second gate electrode 20b, and the same electrical signal is applied to the first sub-electrode 50a and the second sub-electrode 50b, a semiconductor device 1 may operate as a single transistor.

Alternatively, when electrical signals are independently applied to the first gate electrode 20a and the second gate electrode 20b, and electrical signals are independently applied to the first sub-electrode 50a and the second sub-electrode 50b, the semiconductor device 1 may operate as two transistors. For example, the oxide semiconductor layer 10, the first gate electrode 20a, the first gate insulating layer 30a, the first electrode 40, and the first sub-electrode 50a may operate as one transistor, and the oxide semiconductor layer 10, the second gate electrode 20b, the second gate insulating layer 30b, the first electrode 40, and the second sub-electrode 50b may operate at another transistor.

The barrier layer 70 may be arranged on a surface of the oxide semiconductor layer 10, wherein the surface of the oxide semiconductor layer 10 is not in contact with the first electrode 40, the second electrode 50, and the gate insulating layer 30. Then, the insulating layer 60 filling up an empty space of the semiconductor device may be arranged. That is, the barrier layer 70 may be arranged between the oxide semiconductor layer 10 and the insulating layer 60. For example, the barrier layer 70 may include a first barrier layer 70a arranged between the first vertical extension 10b and the insulating layer 60 and a second barrier layer 70b arranged between the second vertical extension 10c and the insulating layer 60.

The barrier layer 70 may include a material having less oxide formation energy than a material included in the oxide semiconductor layer 10 and a material included in the insulating layer 60. For example, the barrier layer 70 may include a material having oxide formation energy of −800 kJ/mol at about 1 atmosphere and at about 100° C. The barrier layer 70 may be an oxide including at least one of lithium (Li), beryllium (Be), magnesium (Mg), aluminum (Al), calcium (Ca), scandium (Sc), strontium (Sr), yttrium (Y), zirconium (Zr), barium (Ba), lanthanum (La), and/or hafnium (Hf).

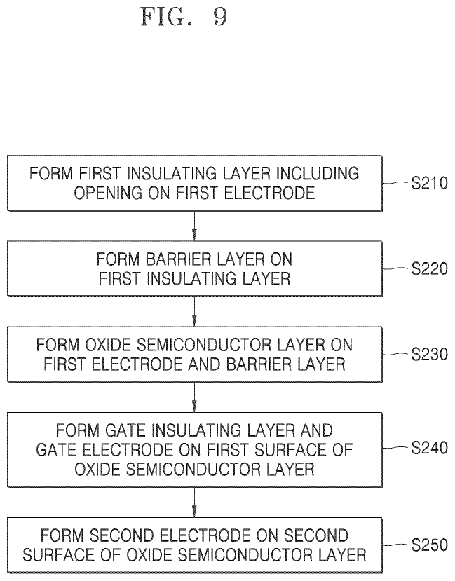

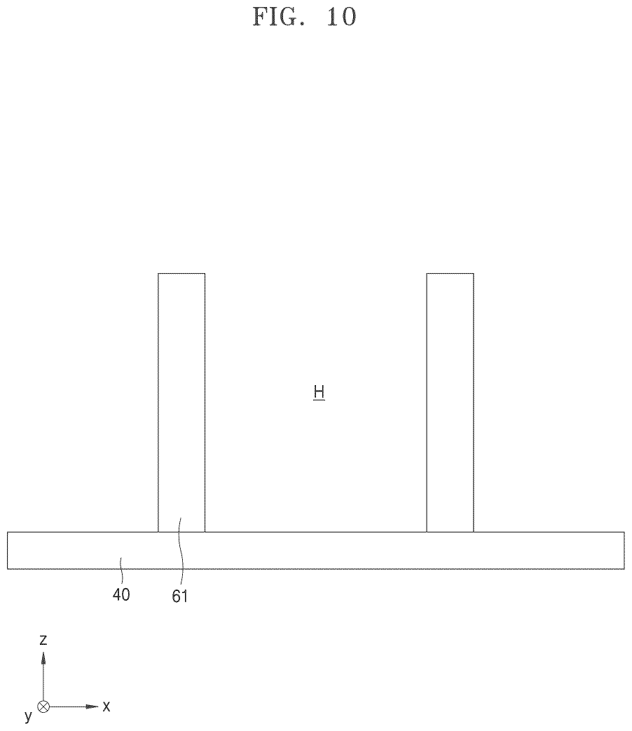

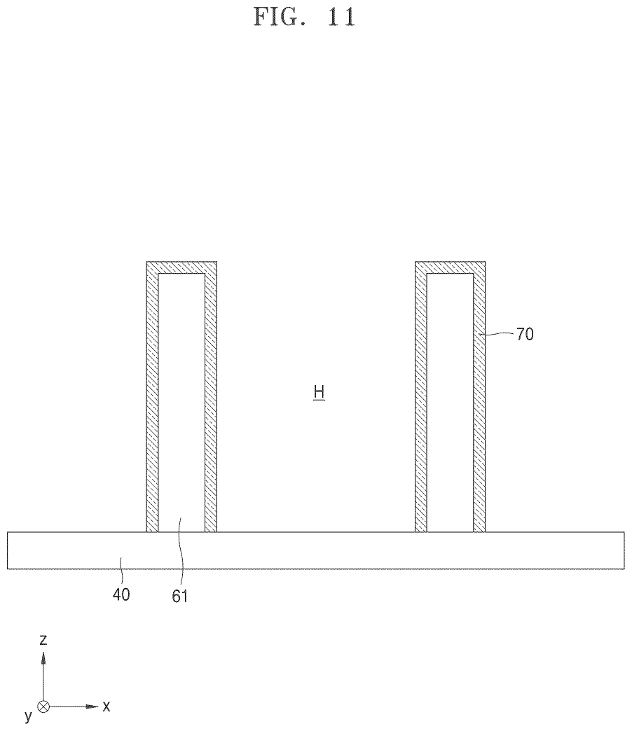

FIG. 9 is a flowchart illustrating a method of manufacturing a semiconductor device according to at least one example embodiment, and FIGS. 10 to 17 are each a flowchart illustrating a method of manufacturing the semiconductor device of FIG. 8.

Referring to FIGS. 9 and 10, on the first electrode 40, a first insulating layer 61 defining an opening H partially exposing the electrode may be formed (S210). A plurality of first insulating layers 61 extending in the second horizontal direction (Y-axis direction) may be deposited on the first electrode 40 extending in the first horizontal direction (X-axis direction). The first insulating layers 61 may be stacked in a vertical direction (Z-axis direction) to have a certain height.

Referring to FIGS. 9 to 11, the barrier layer 70 may be formed on the first insulating layer 61 (S220). The barrier layer 70 may entirely over an exposed surface of the first insulating layer 61.

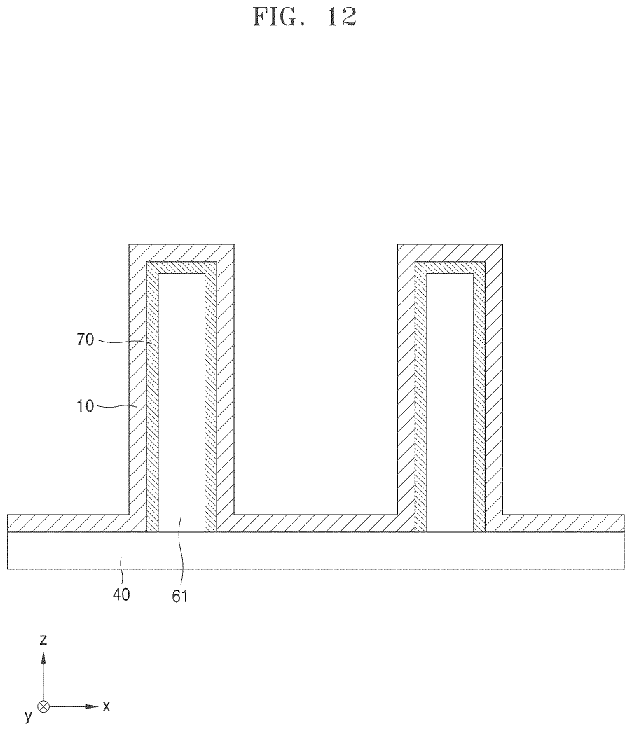

Referring to FIGS. 9 and 12, the oxide semiconductor layer 10 may be formed on the first electrode 40 and the first insulating layer 61 (S230). The oxide semiconductor layer 10 may be deposited by using a thermal-atomic layer deposition (ALD) method, a plasma enhanced-ALD (PE-ALD) method, a sputtering method, a wet-processing method, etc. The oxide semiconductor layer 10 may have a U-shaped cross-section.

Referring to FIGS. 9, 13, 14, and 15, the gate insulating layers (30a and 30b) and the gate electrodes (20a and 20b) may be formed on a first surface of the oxide semiconductor layer 10.

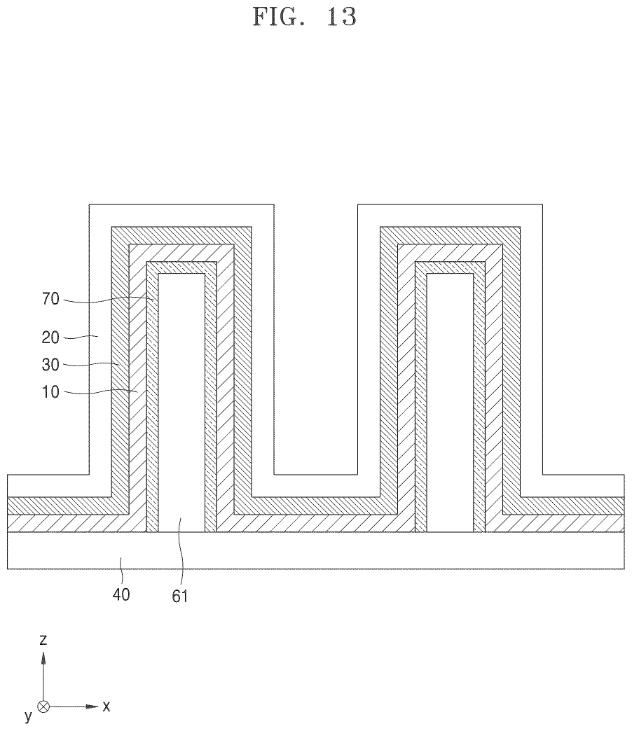

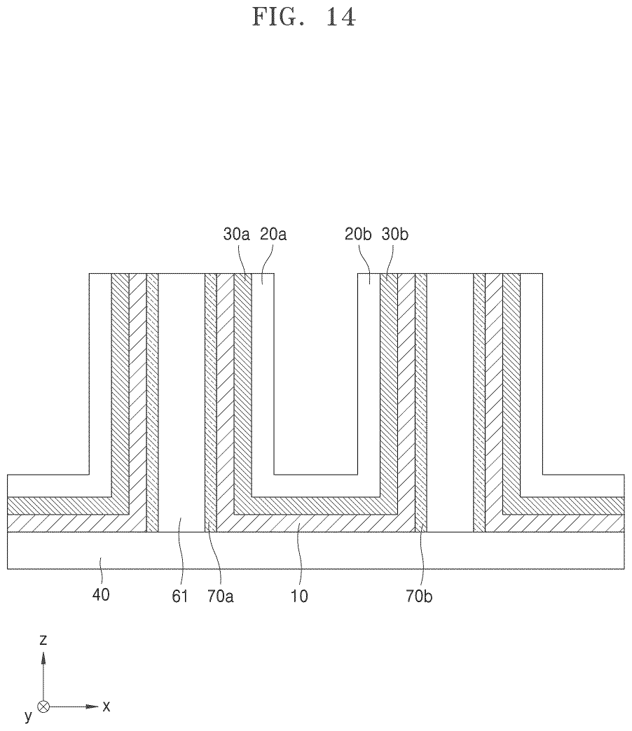

For example, as illustrated in FIG. 14, the gate insulating layer 30 and the gate electrode 20 may be formed on the surface of the oxide semiconductor layer 10 by partially etching the gate insulating layer 30 and the gate electrode 20 of the structure illustrated in FIG. 13, such that a partial surface of the oxide semiconductor layer 10 (for example, a bottom portion) may be exposed. In addition, the gate electrode 20, the gate insulating layer 30, and the oxide semiconductor layer 10 may be etched in a direction to an upper portion of the first insulating layer 61 to expose upper surface of the first insulating layer 61. The heights of the upper surface of the first insulating layer 61, the upper surfaces of the first gate electrode 20a and the second gate electrode 20b, and the upper surfaces of the first gate insulating layer 30a and the second gate insulating layer 30b from the first electrode 40 may be identical to each other.

As a result, as illustrated in FIG. 14, the gate electrode 20 may be divided into the first gate electrode 20a and the second gate electrode 20b, and the gate insulating layer 30 may be divided into the first gate insulating layer 30a and the second gate insulating layer 30b.

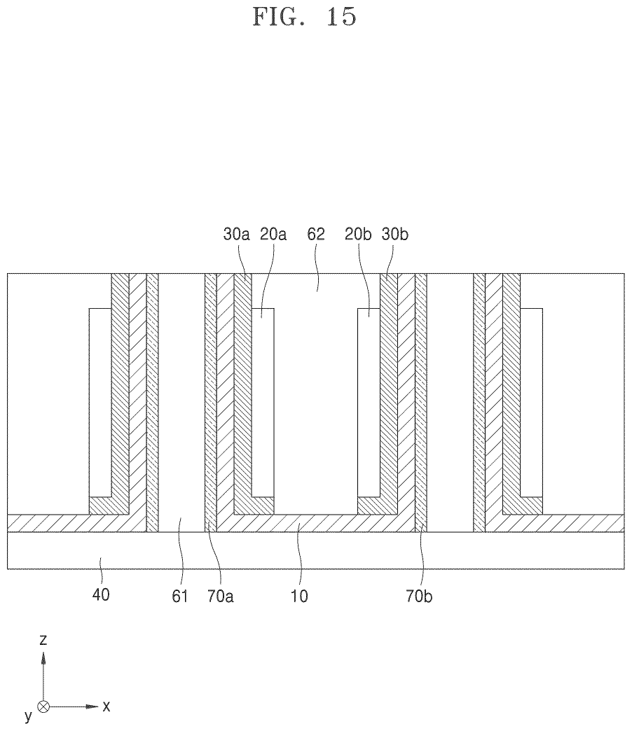

Referring to FIG. 15, by etching the first gate electrode 20a and the second gate electrode 20b once again, the height of the upper surfaces of the first gate electrode 20a and the second gate electrode 20b (e.g. a distance from the first electrode 40) may be lower than the height of the upper surfaces of the first gate insulating layer 30a and the second gate insulating layer 30b.

The second insulating layer 62 may be deposited from the surface of the bottom portion 10a of the oxide semiconductor layer 10 to the same height as the upper surface of the oxide semiconductor layer 10. The height of the upper surface of the second insulating layer 62 may be identical to the height of the upper surface of the first insulating layer 61 and the height of the upper surface of the oxide semiconductor layer 10.

The second electrode 50 may be formed on a second surface different from the first surface of the oxide semiconductor layer 10 (S250).

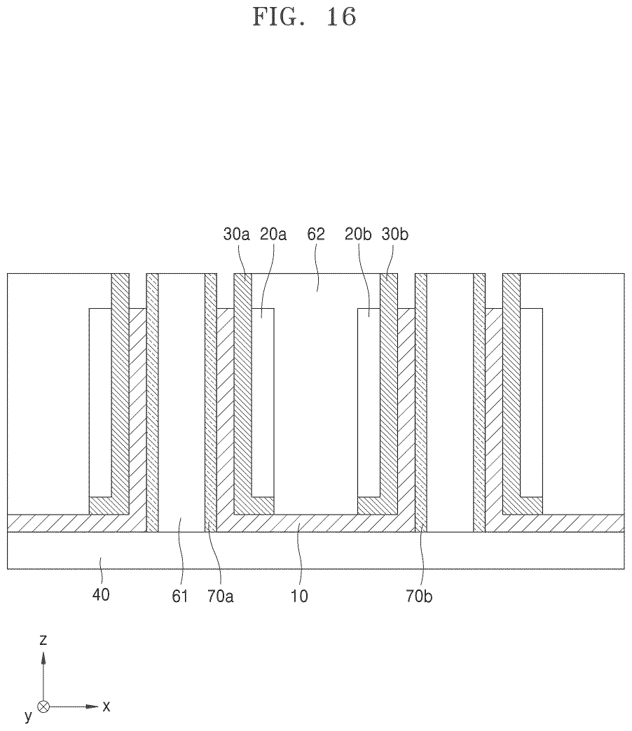

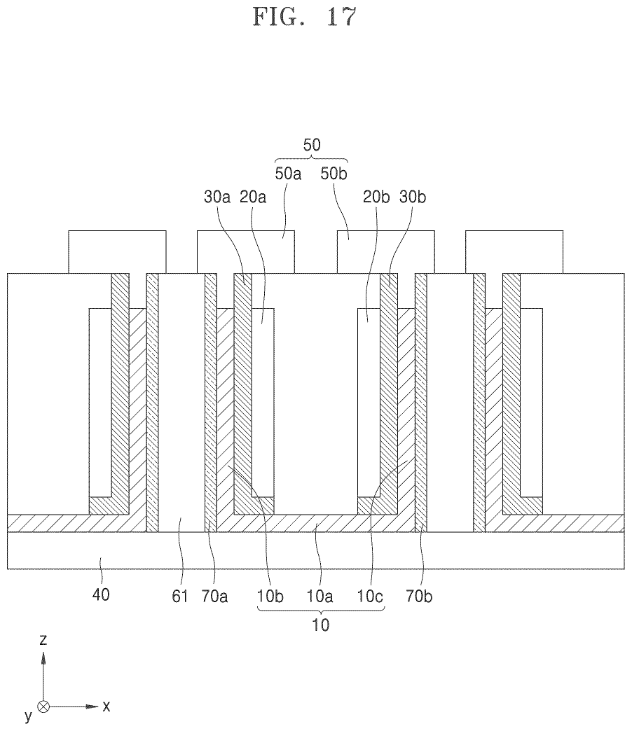

As illustrated in FIGS. 16 and 17, the upper portion of the oxide semiconductor layer 10 may be partially etched, and the second electrode 50 may be formed on the etched oxide semiconductor layer 10. After depositing a metal layer on the second insulating layer 62, the first gate insulating layer 30a, the second gate insulating layer 30b, and the oxide semiconductor layer 10, the metal layer may be etched to partially expose the first insulating layer 61 and the second insulating layer 62. In this manner, the second electrode 50 may be formed from the metal layer.

The semiconductor device according to at least one example embodiment may be a component of a memory apparatus.

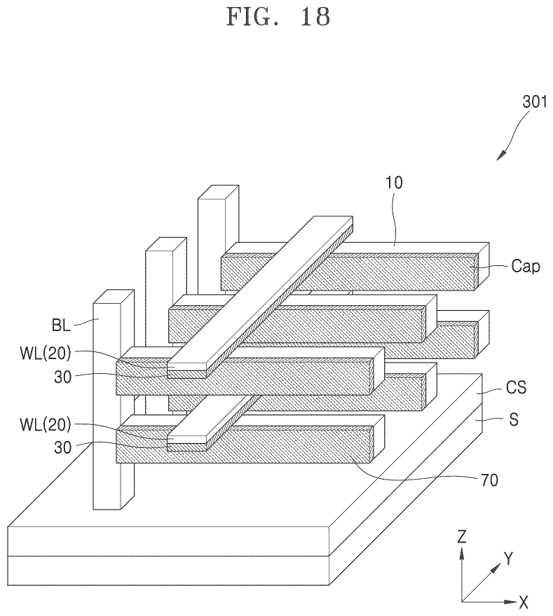

FIG. 18 is a perspective view illustrating a schematic structure of a vertically stacked memory apparatus 301 according to at least one example embodiment. Referring to FIG. 18, the vertically stacked memory apparatus 301 may include a plurality of bit lines BL extending in the first direction (Z direction), a plurality of oxide semiconductor layers 10 respectively connected to the plurality of bit lines BL and extending in a second direction (X direction) vertically intersecting with the first direction, a plurality of capacitors Cap electrically connected to the plurality of oxide semiconductor layers 10, respectively, and a plurality of word lines WL extending to intersect with the plurality of oxide semiconductor layers 10 in the third direction (Y direction) vertically intersecting with the first direction and the second direction. Although FIG. 18 illustrates that each of the plurality of word lines WL crosses on a corresponding oxide semiconductor layer 10 of the plurality of oxide semiconductor layers 10, the disclosure is not limited thereto, and the word lines WL may cross under the oxide semiconductor layers 10.

In addition, the vertically stacked memory apparatus 301 may further include the substrate S for growth and a driving circuit board CS arranged on the substrate S for growth. The driving circuit board CS may include circuits for performing input/output operations for receiving data input from an external circuit connected thereto or outputting data to the outside and for performing operations for recording data on the capacitors Cap or reading data recorded on the capacitors Cap.

The plurality of bit lines BL may be arranged to be perpendicular to the upper surface of the driving circuit board CS on the driving circuit board CS. Although FIG. 18 illustrates that only three bit lines BL are arranged in line and apart from each other in the third direction, a larger number of bit lines BL may be arranged in a 2D manner. For example, the plurality of bit lines BL extending in the vertical direction, i.e., the first direction may be arranged in a 2D manner on the driving circuit board CS and spaced apart from each other in the second direction and the third direction. The plurality of bit lines BL may be arranged in parallel with each other.

The plurality of oxide semiconductor layers 10 connected to one corresponding bit line BL from among the plurality of bit lines BL may be spaced apart from each other in the first direction. Although FIG. 18 illustrates only two oxide semiconductor layers 10 in relation to one bit line BL, a larger number of oxide semiconductor layers 10 may be spaced apart from each other in the first direction. In addition, in the same layer, a plurality of oxide semiconductor layers 10 may be spaced apart from each other in third direction in parallel manner. The plurality of oxide semiconductor layers 10 arranged in the same layer may respectively be connected to corresponding bit lines from among the plurality of bit lines BL. Similar to the plurality of bit lines BL, the plurality of oxide semiconductor layers 10 may be spaced apart from each other in the second direction and the third direction in a 2D manner. Each of the plurality of oxide semiconductor layers 10 may extend in the second direction. A first end of each of the plurality of oxide semiconductor layers 10 may be electrically connected on a corresponding bit line from among the plurality of bit lines BL. A second end of each of the plurality of oxide semiconductor layers 10, which is opposite to the first end, may be electrically connected to the capacitor Cap.

Although FIG. 18 illustrates the capacitor Cap as one block, the capacitor Cap may include a first electrode, a second electrode, and a dielectric layer arranged between the first electrode and the second electrode. The first electrode of the capacitor Cap may be electrically connected to the second electrode of the corresponding oxide semiconductor layer 10 from among the plurality of oxide semiconductor layers 10. Accordingly, one oxide semiconductor layer 10 may be connected to one capacitor Cap. Although it is not shown in the drawings, the second electrode of the capacitor Cap may be connected to a ground line of the vertically stacked memory apparatus.

The word line WL may extend in the third direction to cross on the plurality of corresponding oxide semiconductor layers 10. The plurality of word lines WL may be spaced apart from each other in the first direction. Although FIG. 18 illustrates only one word line WL arranged on one layer, a plurality of word lines WL may be spaced apart from each other in the second direction on one layer in a parallel manner.

The gate insulating layer 30 may be arranged between the oxide semiconductor layer 10 and the word line WL. Although it is not shown in FIG. 18, a vertically stacked memory apparatus 200 may further include an insulating material filled in spaces between the plurality of bit lines BL, between the plurality of oxide semiconductor layers 10, and between the plurality of word lines WL.

One oxide semiconductor layer 10 may form one oxide semiconductor transistor together with one corresponding word line WL and bit line BL and the first electrode of the capacitor. The first electrode of the oxide semiconductor transistor may be a component of the bit line BL, the gate electrode may be a component of the word line WL, and the second electrode may be the first electrode of the capacitor Cap. However, the disclosure is not limited thereto. The first electrode, the gate electrode, and the second electrode may be provided as a separate layer and may be electrically connected to a bit line LV, the word line WL, and the first electrode of the capacitor Cap.

As the word line WL may function as the gate electrode of the oxide semiconductor transistor, when a gate signal greater than a threshold voltage is applied to the word line WL, a current may flow along the oxide semiconductor layer 10. In this manner, the corresponding bit line BL and the capacitor Cap may be electrically connected to each other, and accordingly, data may be recorded to the capacitor Cap, or data recorded to the capacitor Cap may be read.

As such, one oxide semiconductor layer 10 and one capacitor Cap corresponding thereto may form a memory cell. A vertically stacked memory apparatus 301 according to at least one example embodiment may include a plurality of memory cells arranged in a 2D manner on one layer. The vertically stacked memory apparatus 301 may have a structure in which a plurality of layers including a plurality of memory cells arranged in a 2D manner are stacked. Accordingly, the degree of integration of the memory cells may be high, which leads to improved recording capacity of the vertically stacked memory apparatus 301.

The barrier layer 70 may be arranged on at least a surface of the oxide semiconductor layer 10, wherein the surface of the oxide semiconductor layer 10 is not in contact with the bit line, the capacitor, and the gate insulating layer 30. Then, an insulating layer (not shown for clarity) may be filled in an empty space of the memory apparatus. That is, the barrier layer 70 may be arranged between the oxide semiconductor layer 10 and the insulating layer. The insulating layer may be the same as and/or substantially similar to the insulating layer 60 described above. The barrier layer 70 may include a material having less oxide formation energy than a material included in the oxide semiconductor layer 10 and a material included in the insulating layer. For example, the barrier layer 70 may include a material having oxide formation energy of −800 kJ/mol at about 1 atmosphere and at about 100° C. The barrier layer 70 may be an oxide including at least one of lithium (Li), beryllium (Be), magnesium (Mg), aluminum (Al), calcium (Ca), scandium (Sc), strontium (Sr), yttrium (Y), zirconium (Zr), barium (Ba), lanthanum (La), and hafnium (Hf).

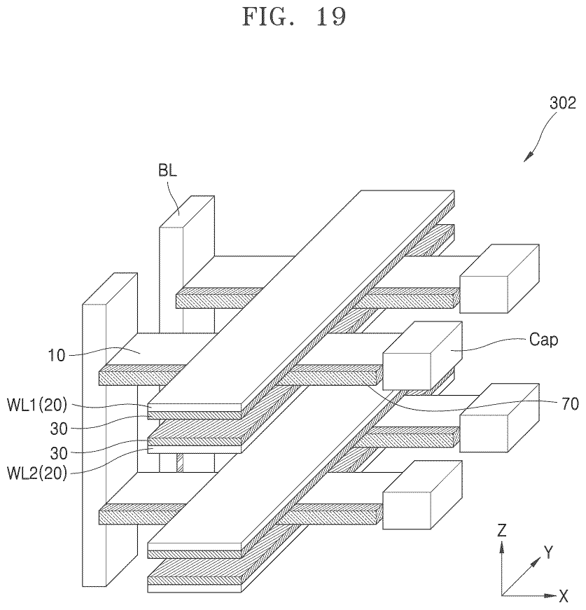

FIG. 19 is a perspective view illustrating a schematic structure of a vertically stacked memory apparatus 302 according to at least one example embodiment. Referring to FIGS. 18 and 19, the vertically stacked memory apparatus 302 of FIG. 19 may have a double gate structure. For example, the vertically stacked memory apparatus 302 may include a first word line WL1 extending in the third direction to cross on the plurality of oxide semiconductor layers 10 arranged at the same layer and a second word line WL2 extending in the third direction to cross under the plurality of oxide semiconductor layers 10 arranged at the same layer. The first word line WL1 and the second word line WL2 may be arranged apart from each other in the first direction with the corresponding oxide semiconductor layer 10 arranged therebetween and may face each other in a parallel manner. In other words, each of the plurality of word lines WL illustrated in FIG. 19 may include the first word line WL1 and the second word line WL2 which are arranged to face each other in a parallel manner and apart from each other in the first direction with the corresponding oxide semiconductor layer 10 arranged therebetween from among the plurality of oxide semiconductor layers 10.

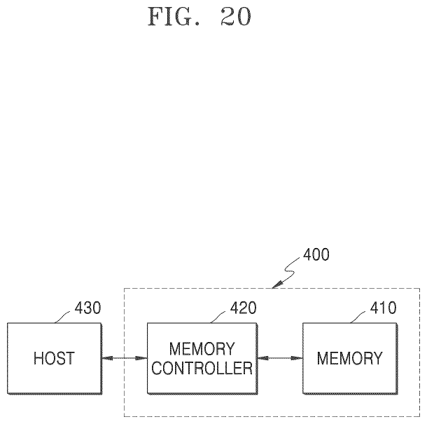

One oxide semiconductor layer 10 may form one oxide semiconductor transistor together with one corresponding first word line WL1 and second word line WL2. Operations of the oxide semiconductor transistor may be controlled by the first word line WL1 arranged on the oxide semiconductor layer 10 and the second word line WL2 arranged under the oxide semiconductor layer 10. Accordingly, the driving reliability of the oxide semiconductor transistor may be improved. As other components of a vertically stacked memory apparatus 302 illustrated in FIG. 20 may be the same as the structures of the vertically stacked memory apparatus 301 illustrated in FIG. 19, any redundant description thereof is omitted.

Although FIGS. 18 and 19 illustrate that the bit lines BL are arranged perpendicular to the upper surface of the driving circuit board CS, and the word lines WL are arranged horizontal with the upper surface of the driving circuit board CS, the disclosure is not limited thereto. The bit lines BL may be arranged horizontal with the upper surface of the driving circuit board CS, and the word lines WL may be arranged perpendicular to the upper surface of the driving circuit board CS. That is, the oxide semiconductor layer 10 and the capacitor Cap may be sequentially arranged from the driving circuit board CS.

FIG. 20 is a block diagram of an electronic system 400 according to at least one example embodiment.

The electronic system 400 may include a memory 410 and a memory controller 420. The memory controller 420 may control the memory 410 to read data from the memory 410 and/or write data on the memory 410 in response to a request from a host 430. At least one of the memory 410 and/or the memory controller 420 may include the semiconductor device according to at least one example embodiment.

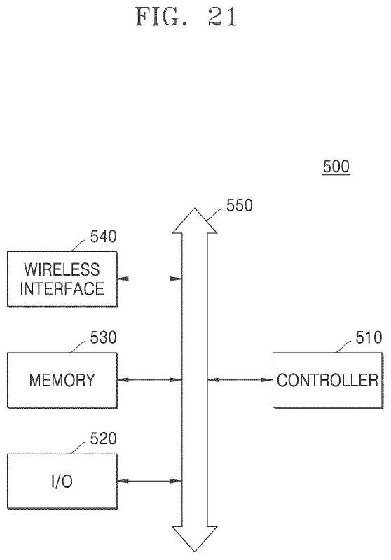

FIG. 21 is a block diagram of an electronic system 500 according to at least one example embodiment.

The electronic system 500 may constitute a wireless communication apparatus or an apparatus configured to transmit and/or receive information under a wireless environment. The electronic system 500 may include a controller 510, an input/output apparatus (I/O) 520, a memory 530, and a wireless interface 540, which are connected to each other through a bus 550.

The controller 510 may include at least one of a microprocessor, a digital signal processor, and any other similar processors. The I/O 520 may include at least one of a keypad, a keyboard, and a display. The memory 530 may be used to store instructions performed by the controller 510. For example, the memory 530 may be used to store user data. The electronic system 500 may use the wireless interface 540 to transmit/receive data through a wireless communication network. The wireless interface 540 may include an antenna and/or a wireless transceiver. The electronic system 400 may include the semiconductor device according to at least one example embodiment.

In the semiconductor device according to at least one example embodiment, as the barrier layer having less oxide formation energy is arranged between the oxide semiconductor layer and the insulating layer, a material exchange between the oxide semiconductor layer and the insulating layer may be reduced.

In the semiconductor device according to at least one example embodiment, even when the oxide semiconductor layer is exposed to hydrogen, the deterioration of the oxide semiconductor layer may be reduced by the barrier layer.

It should be understood that the example embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
an oxide semiconductor layer;
a first electrode and a second electrode spaced apart from each other on the oxide semiconductor layer;
a gate electrode spaced apart from the oxide semiconductor layer;
a gate insulating layer between the oxide semiconductor layer and the gate electrode;
an insulating layer facing a surface of the oxide semiconductor layer, the surface of the oxide semiconductor layer not in contact with the first electrode, the second electrode, and the gate insulating layer; and
a barrier layer between the oxide semiconductor layer and the insulating layer, and including a third element, an oxide formation energy of the third element is less than an oxide formation energy of a first element included in the oxide semiconductor layer and less than an oxide formation energy of a second element included in the insulating layer.

2. The semiconductor device of claim 1, wherein the oxide semiconductor layer includes at least one of indium (In), gallium (Ga), tin (Sn), cadmium (Cd), germanium (Ge), hafnium (Hf), or zinc (Zn).

3. The semiconductor device of claim 1, wherein the oxide formation energy of the third element has is −800 kilojoules per mole (kJ/mol) or less at 1 atmosphere and at 100 degrees Celsius (° C.).

4. The semiconductor device of claim 1, wherein the barrier layer is an oxide including at least one of lithium (Li), beryllium (Be), magnesium (Mg), aluminum (Al), calcium (Ca), scandium (Sc), strontium (Sr), yttrium (Y), zirconium (Zr), barium (Ba), lanthanum (La), or hafnium (Hf).

5. The semiconductor device of claim 1, wherein a thickness of the barrier layer is less than or equal to a thickness of the oxide semiconductor layer.

6. The semiconductor device of claim 1, wherein the barrier layer is in contact with the surface of the oxide semiconductor layer not in contact with the first electrode, the second electrode, and the gate insulating layer.

7. The semiconductor device of claim 1, wherein the barrier layer is in contact with an entirety of the surface of the oxide semiconductor layer not in contact with the first electrode, the second electrode, and the gate insulating layer.

8. The semiconductor device of claim 1, wherein the insulating layer includes at least one of a silicon oxide or a silicon nitride.

9. The semiconductor device of claim 1, wherein the gate insulating layer is an oxide including at least one of hafnium (Hf), zirconium (Zr), aluminum (Al), or silicon (Si).

10. The semiconductor device of claim 1, wherein the third element is also included in the oxide semiconductor layer, and
a content of the third element in the barrier layer is greater than a content of the third element in the oxide semiconductor layer.

11. The semiconductor device of claim 1, wherein the first electrode, the oxide semiconductor layer, and the second electrode are sequentially arranged in a first direction, the first direction perpendicular to a surface of the first electrode, and
the barrier layer, the oxide semiconductor layer, the gate insulating layer, and the gate electrode are sequentially arranged in a second direction, the second direction perpendicular to the first direction.

12. The semiconductor device of claim 11, wherein the oxide semiconductor layer includes, in a cross-sectional view perpendicular to the surface of the first electrode:
a first area extending in the second direction; and
a second area extending from the first electrode towards the second electrode.

13. The semiconductor device of claim 1, further comprising:
a capacitor electrically connected to the oxide semiconductor layer,
wherein the first electrode is a component of a bit line, and the gate electrode is a component of a word line.

14. A method of manufacturing a semiconductor device, the method comprising:
forming a first insulating layer on a first electrode such that the first insulating layer defines an opening exposing the first electrode, the first insulating layer including a first element;
forming a barrier layer on the first insulating layer, the barrier layer including a second element having less oxide formation energy than the first element included in the first insulating layer;
forming an oxide semiconductor layer on the first electrode and the barrier layer;
sequentially forming a gate insulating layer and a gate electrode on a first surface of the oxide semiconductor layer; and
forming a second electrode on a second surface of the oxide semiconductor layer, the second surface being different from the first surface of the oxide semiconductor layer.

15. The method of claim 14, wherein the forming of the gate insulating layer and the gate electrode comprises:
etching the gate insulating layer and the gate electrode such that a surface of the oxide semiconductor layer is exposed, wherein the surface of the oxide semiconductor layer which is exposed is parallel to a surface of the first electrode;
etching the gate insulating layer and the gate electrode such that the gate insulating layer is divided into a first gate insulating layer and a second gate insulating layer, the gate electrode is divided into a first gate electrode and a second gate electrode, and an upper surface of the first insulating layer is exposed; and
partially etching the first gate electrode and the second gate electrode such that a distance of upper surfaces of the first gate electrode and the second electrode from the first electrode is less than a distance of upper surfaces of the first gate insulating layer and the second gate insulating layer from the first electrode.

16. The method of claim 14, wherein the second element included in the barrier layer has less oxide formation energy than a third element included in the oxide semiconductor layer.

17. The method of claim 14, wherein the second element has an oxide formation energy of −800 kilojoules per mole (kJ/mol) or less at 1 atmosphere and at 100 degrees Celsius (° C.).

18. The method of claim 14, wherein the barrier layer is an oxide including at least one of lithium (Li), beryllium (Be), magnesium (Mg), aluminum (Al), calcium (Ca), scandium (Sc), strontium (Sr), yttrium (Y), zirconium (Zr), barium (Ba), lanthanum (La), or hafnium (Hf).

19. The method of claim 14, wherein a thickness of the barrier layer is less than or equal to a thickness of the oxide semiconductor layer.

20. The method of claim 14, wherein the second element is also included in the oxide semiconductor layer, and
a content of the second element in the barrier layer is greater than a content of the second element in the oxide semiconductor layer.
